(19) United States
(12) Patent Application Publication
(10) Pub. No.: US 2025/0113586 A1
(43) Pub. Date: Apr. 3, 2025

(54) NBTI REDUCTION AND RELIABILITY IMPROVEMENT FOR SELECTIVE LAYOUTS

(71) Applicant: Intel Corporation, Santa Clara, CA (US)

(72) Inventors: Rahul PANDEY, Hillsboro, OR (US); Yang CAO, Beaverton, OR (US); Rahul RAMAMURTHY, Hillsboro, OR (US); Jubin NATHAWAT, Hillsboro, OR (US); Michael L. HATTENDORF, Portland, OR (US); Jae HUR, Hillsboro, OR (US); Anant H. JAHAGIRDAR, Portland, OR (US); Steven R. NOVAK, Portland, OR (US); Tao CHU, Portland, OR (US); Yanbin LUO, Portland, OR (US); Minwoo JANG, Portland, OR (US); Paul A. PACKAN, Hillsboro, OR (US); Owen Y. LOH, Portland, OR (US); David J. TOWNER, Portland, OR (US)

(21) Appl. No.: 18/374,929

(22) Filed: Sep. 29, 2023

(51) Int. Cl. H01L 29/51; H01L 21/3115; H01L 29/40; H01L 29/78

(52) U.S. Cl. CPC H10D 64/683; H01L 21/31155; H10D 30/6211; H10D 64/01

(57) ABSTRACT

An integrated circuit structure comprises a fin extending from a substrate, the fin comprising source and drain regions, and a channel region between the source and drain regions. A multilayer high-k gate stack comprising a plurality of materials extends conformally over the fin over the channel region. A gate electrode is over and on a topmost material in the multilayer high-k gate stack. Fluorine is implanted in the substrate beneath the multilayer high-k gate stack or in the plurality of materials comprising the multilayer high-k gate stack.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and state-of-the-art fabrication processes may limit the possibility to further extend them into the sub-10 nm range. Consequently, fabrication of the functional components needed for future technology nodes may require the introduction of new methodologies or the integration of new technologies in current fabrication processes or in place of current fabrication processes.

For example, in a FinFET, a type of non-planar transistor built around a thin strip of semiconductor material referred to as a fin, a gate oxide is a dielectric/insulating layer that separates the gate terminal of the transistor from the underlying source and drain terminals. Negative-bias temperature instability (NBTI) is a reliability issue in integrated circuits (ICs) that manifests as an increase in the threshold voltage of MOSFET devices, particularly p-channel MOS when they are subjected to negative gate bias and elevated temperatures. This increase in threshold voltage can lead to a decrease in the device's performance, such as its speed and current drive.

### BRIEF DESCRIPTION OF THE DRAWINGS

FIG. 1A shows one example of a portion of an IC device consistent with the present disclosure, in this case a portion of a FinFET.

FIG. 1B shows a view of a cross-section X-X′ of the IC device.

FIGS. 2A-2D are diagrams illustrating cross-sections of the multilayer high-k gate dielectric stack at an interface with the channel region showing different specific fluoride implant locations within the multilayer high-k gate dielectric stack according to various embodiments.

FIG. 3 shows an embodiment where patterning is used to selectively open a target layout configuration that needs an NBTI benefit, which in this example is a PMOS layout.

FIG. 4 illustrates graphs of simulation result profiles when fluorine is implanted in the dummy oxide to improve the amount of F-dose in silicon.

FIGS. 5A-5I illustrate cross-sectional views for respective stages of processing to fabricate an IC device (configured to provide transistor functionality) having a multilayer high-k gate stack extending under a gate structure and over an existing semiconductor fin structure.

FIGS. 6A and 6B are top views of a wafer and die that include NBTI reduction based on a fluorine implant, in accordance with one or more of the embodiments disclosed herein.

FIG. 7 illustrates a block diagram of an electronic system, in accordance with an embodiment of the present disclosure.

FIG. 8 is a cross-sectional side view of an integrated circuit (IC) device assembly that may include NBTI reduction based on a fluorine implant, in accordance with one or more of the embodiments disclosed herein.

FIG. 9 illustrates a computing device in accordance with one implementation of the disclosure.

### DESCRIPTION OF THE EMBODIMENTS

Negative-bias temperature instability (NBTI) reduction and reliability improvement for selective integrated circuit layouts are described. In the following description, numerous specific details are set forth, such as specific materials, to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order-dependent. In particular, these operations need not be performed in the order of presentation.

Certain terminology may also be used in the following description for reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

One or more embodiments described herein are directed to planar and non-planar transistor structures (e.g., FinFET or gate-all-around FET) fabricated with a gate oxide comprising a multilayer high-k gate stack of materials, with fluorine implanted in specific locations in the transistor structures to enable high-performance transistors with improved negative bias temperature instability (NBTI). Such transistor structures implanted with fluorine improve GOX/interface quality, which reduces NBTI and gate leakage without a significant impact on performance. Embodiments may include or pertain to one or more of transistors, semiconducting oxide materials, and system-on-chip (SoC) technologies of future technology nodes.

To provide context, a FinFET is one type of non-planar transistor that is built around a thin strip of semiconductor material (referred to as the “fin”). The transistor includes the standard field effect transistor (FET) nodes/components: a gate, a gate dielectric, a source region, and a drain region. During operation, a conductive channel of the device resides on the outer sides of the fin beneath the gate dielectric. Specifically, current runs along “sidewalls” of the fin as well as along the top side of the fin. Because the conductive channel essentially resides along the three different outer, planar regions of the fin, such a FinFET is typically referred to as a “tri-gate” FinFET. Other types of FinFETs exist (such as “double-gate” FinFETs in which the conductive channel principally resides only along both sidewalls of the fin and not along the top side of the fin).

Typically, fabricating a transistor structure includes depositing a dielectric material into a given space to form a gate oxide (GOX) or dielectric to provide at least some electrical insulation between two adjoining structures, e.g., a fin and a gate. A common material for a gate oxide is silicon dioxide, which has a dielectric constant of around 3.8. However, as improvements to semiconductor fabrication processing continue to reduce the size of transistor structures, limits are placed on gate oxide thickness scaling. As a result, there is expected to be a growing premium placed on incremental improvements to techniques for overcoming the limits of gate oxide thickness scaling and the inversion charge of conventional gate oxides, while reducing negative bias temperature instability (NBTI).

Referring now to the first aspect of the disclosed embodiments, an integrated circuit structure has a fin that extends from the substrate. The fin includes source and drain regions, with a channel region situated between them. A multilayer high-k gate stack that consists of a variety of materials extends conformally over the fin, spanning the channel region. A gate electrode is placed over and on top of the highest high-k material in the multilayer high-k gate stack. Additionally, fluorine is implanted in a location of one or more materials comprising the substrate and/or the multilayer high-k gate stack. In one embodiment, high-k materials are used for the gate dielectric, where the high-k materials have a dielectric constant k greater than 7. In embodiments, the integrated circuit may comprise a non-planar transistor (e.g., multi-gate, nanowire, or nanoribbon device) or a planar transistor.

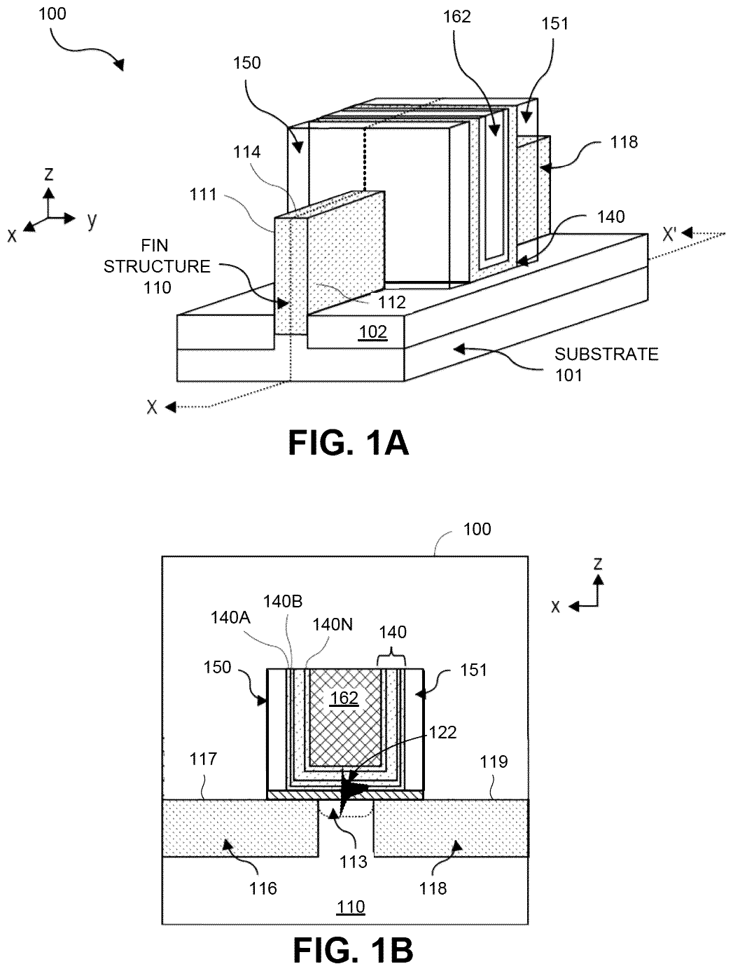

FIG. 1A shows one example of a portion of an IC device 100 consistent with the present disclosure, in this case a portion of a FinFET. As shown, IC device 100 includes a substrate 101, a trench dielectric 102 on substrate 101, and a fin structure 110 disposed in a trench which is formed by trench dielectric 102. Fin structure 110 comprises, for example, a top surface 114 and a pair of laterally opposite sidewalls (sidewall 111 and opposing sidewall 112, respectively). In some embodiments, portions of fin structure 110 which are vertically offset from one another comprise different respective group III-V (and/or other) semiconductor materials. In one example embodiment, sizes of the fin structure may be sub 50 nm in width, and sub 200 nm in height.

Substrate 101 is formed of any of a variety of materials that are suitable for use as a substrate of a semiconductor device, and in particular as a substrate for non-planar transistors such as FinFETS and multi-gate transistors. Non-limiting examples of such suitable materials include silicon (Si), germanium (Ge), silicon-germanium (SiGe), silicon-carbide (SiC), sapphire, a group III-V semiconductor, a silicon-on insulate (SOI) substrate, combinations thereof, and the like. Without limitation, in some embodiments substrate 101 is formed from or includes single-crystal silicon.

Trench dielectric 102, which may also comprise multiple layers, is formed from any of a variety of materials that are suitable for use as a trench dielectric material of a non-planar semiconductor device. Non-limiting examples of materials for the trench dielectric 102 may include oxides, nitrides and alloys, such as but not limited to silicon oxide (SiO₂), silicon nitride (SiN), silicon oxycarbide (SiCO), silicon carbon oxynitride (SiCON), silicon carbonitride (SiCN), combinations thereof, and the like.

FIG. 1B shows a view of a cross-section X-X′ of IC device 100. A non-planar transistor of IC device 100 comprises structures that are variously disposed in or on fin structure 110. For example, such a non-planar transistor may include a channel region 113, two doped source or drain (“SD”) structures 116, 118 at opposite ends of the channel region 113, and raised epitaxial (epi) source or drain regions 117, 119.

According to the disclosed embodiments, a gate structure of the non-planar transistor comprises a gate electrode 162 and a multilayer high-k gate dielectric stack 140 comprising a plurality of materials 140A-140N extending conformally over the fin structure 110 over channel region 113. In one embodiment, the plurality of materials 140A-140N comprising the multilayer high-k gate dielectric stack 140 may comprise any combination of: at least one of: Silicon (Si), Oxide (Ox), Nitride (N), Titanium (Ti), Tantalum (Ta), and Amorphous silicon (a-Si); and at least one of Hafnium (Hf), Zirconium (Zr), Aluminum (Al), and Cyanide (CN). Specific examples of high-k materials that may be used include, but are not limited to, Hafnium oxide (HfO₂), Zirconium oxide (ZrO₂), Aluminum oxide (Al₂O₃), and Hafnium Zirconium oxide (HfZrOx).

A gate electrode 162 is over and on a topmost material in the multilayer high-k gate dielectric stack 140. More particularly, gate electrode 162 extends over and across a portion of fin structure 110 in a region between insulation spacers 150, 151, which are shown as transparent in FIG. 1A to further show features of IC device 100. In some embodiments, gate electrode 162 comprises a metal. The gate electrode 162 may include, for example, an elemental metal layer, a metal alloy layer, or a laminate structure of either or both. In some embodiments, the gate electrode 162 may comprise a metal nitride, such as TiN or TiAlN. Other alloy constituents may also be employed, such as, but not limited to C, Ta, W, Pt, and Zn. Materials comprising the channel region 113 may include, but are not limited to, Silicon (Si), Germanium (Ge), Indium (In), Gallium (Ga), Arsenic (As), and Antimony (Sb), e.g., Si, SiGe, Ge, InGaAs, GaSb and Group III-, IV, V semiconductor materials.

Negative-bias temperature instability (NBTI) is a serious problem for ICs because it can lead to a decrease in a device's performance and reliability. NBTI may manifest as an increase in the threshold voltage of MOSFET devices, particularly p-channel MOS devices (PMOS) when they are subjected to negative gate bias and elevated temperatures. This increase in threshold voltage can lead to a decrease in the device's performance, such as its speed and current drive. NBTI is believed to be caused by the existence or generation of interface traps (ITs) or bulk traps in the gate oxide. Interface and bulk oxide traps are charged defects that can trap electrons or holes, and their presence can alter the electrical properties of the gate oxide.

In today's process nodes, scaled electrical oxide thickness (TOXE) in an MOS transistor has been identified as one of several key performance boosters, such as by minimizing short channel effects and increasing gate coupling to channel. However, scaled TOXE can also introduce problems in technology scaling by degrading reliability metrics like breakdown-Voltage and NBTI. For example scaled TOXE may yield as high as ˜20% in performance benefit, but at the same time it can degrade NBTI by approximately 2.5-3×.

Conventional approaches to target NBTI typically include thermal annealing, which is a process of heating the device to a high temperature to help passivate interface traps from the gate oxide. Example thermal anneals used to target NBTI typically include interface passivation using fluorine (F) anneals, gas anneal (FGA) anneals, or high-pressure deuterium (D2) anneals. However, the use of such thermal anneals using F, FGA, and D2 naturally increases transition layer gate oxide thickness, which results in performance loss due to loss of gate field. Also, this approach applies equally to all device types, NMOS and PMOS, and some devices degrade significantly more than others. The problem of NBTI is likely to become more severe as ICs continue to shrink and the gate oxide thickness continues to decrease.

Referring to FIG. 1B, according to the disclosed embodiments, planar and non-planar transistor structures are fabricated that improve or mitigate NBTI by implanting the IC device 100 with fluorine 122 in a specific location of: i) the substrate 101 beneath the multilayer high-k gate stack, ii) the plurality of materials comprising the multilayer high-k gate dielectric stack 140, or iii) both the substrate 101 and the multilayer high-k gate dielectric stack 140. The fluorine 122 may be implanted in various locations of the substrate and the material layers comprising the multilayer high-k gate dielectric stack 140 based on when the implant is performed during fabrication of the multilayer high-k gate dielectric stack 140. The timing of the implant during fabrication of the multilayer high-k gate dielectric stack 140 results in different specific fluorine implant locations within the various materials. The different fluorine implant locations have different/higher performance to reliability trade-offs.

The disclosed embodiments provide process solutions to improve gate oxide (GOX) and interface quality, while reducing NBTI and gate leakage for selective layouts. Improved performance includes improvement in gate capacitance and field-effect mobility on PMOS. In addition, the disclosed embodiments benefit associated process parameters without significant loss of performance. Improved reliability on PMOS includes improved NBTI, breakout voltage, hot carrier degradation, and 1/f noise.

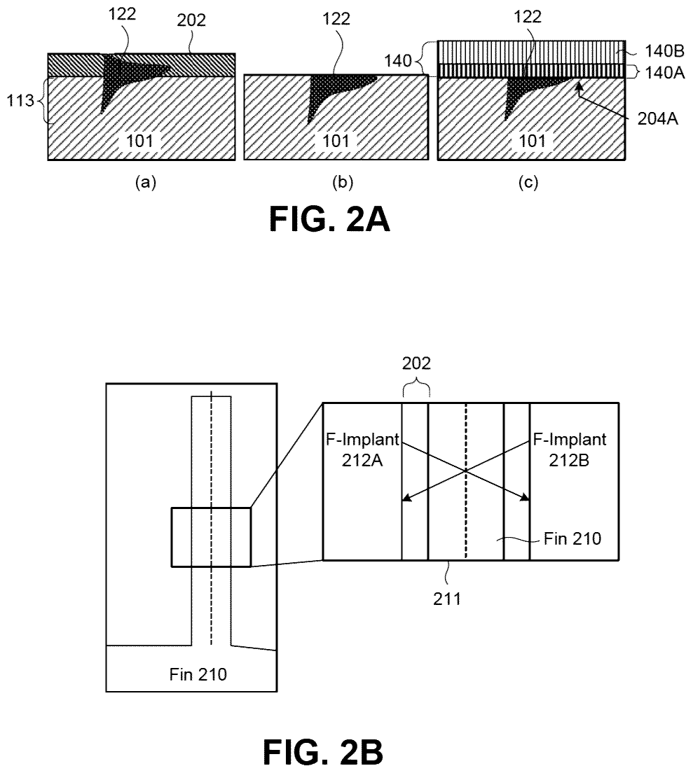

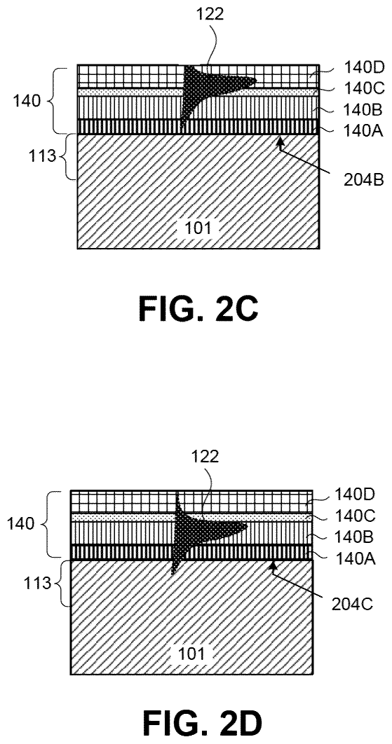

FIGS. 2A-2D are diagrams illustrating cross-sections of the multilayer high-k gate dielectric stack at an interface with the channel region showing different specific fluoride implant locations within the multilayer high-k gate dielectric stack according to various embodiments, where like components from FIG. 1 have like reference numerals.

FIG. 2A shows an embodiment of a process flow comprising steps (a), (b), and (c), where the fluorine 122 is implanted only in substrate 101 beneath the multilayer high-k gate dielectric stack 140. In this embodiment, a dummy gate oxide (GOX) 202 is first formed on substrate 101 over a channel region 113 between source and drain regions at step (a). In step (b), fluorine 122 is implanted in the dummy GOX 202 over the channel region 113, resulting in the fluorine 122 being located in both the dummy GOX 202 and the substrate 101. The dummy GOX 202 is then removed from the substrate 101 with the fluorine 122 remaining in the substrate 101 localized adjacent to the interface. In step (c), the multilayer high-k gate dielectric stack 140 is formed on the substrate 101 in the channel region 113 over the fluorine 122.

In this example, the plurality of materials 140A-140B comprising the multilayer high-k gate dielectric stack 140 is shown comprising a transition material 140A and high-k 140B. As shown, fluorine 122 is located in the substrate 101 adjacent to interface 204A with the multilayer high-k gate dielectric stack 140 in the channel region 113. The implementation of implanting the fluorine 122 in the substrate 101 prior to deposition of the multilayer high-k gate dielectric stack 140 results in no gate-to-channel capacitance loss in gate-channel capacitance and avoids implant damage on high-k 140B. In one embodiment, the channel region 113 may comprise Si, SiGe, Ge, InGaAs, GaSb, or Group III, IV, or V semiconductor materials

FIG. 2B illustrates a fin and a process for implanting the fluorine in the substrate according to one example implementation. Enlarged view 211 shows a cross-section of fin 210, which is covered on both sides by dummy gate oxide (GOX) 202. According to one aspect of the disclosed embodiments, fluorine is implanted in at least two sides of fin 210 (2X) for increased fluorine uniformity. A first F-implant 212A is performed on one side of the fin 210 and a second F-implant 212B is performed on the opposite side of fin 210. Both implants may be performed at a tilt angle of approximately 20°-45° from the vertical of the fin 210. The fluorine dose may be approximately 1e14 to 7e14 and at a temperature of approximately 25 C to 150 C. Additional F-implants may also be performed as necessary, e.g., three sides (3×) or all four sides (4×) of the fin. According to the disclosed embodiments, patterning at dummy GOX is a safe solution to include the F-Implant in the gate loop since the dummy GOX is then removed followed by the high-k gate stack fabrication, significantly reducing the possibility of high-k contamination.

FIG. 2C shows an embodiment where the fluorine 122 is implanted into the multilayer high-k gate dielectric stack 140 after the last or topmost material of the multilayer high-k gate dielectric stack 140 is deposited. In this example, the plurality of materials 140A-140D comprising the multilayer high-k gate dielectric stack 140 is shown comprising transition material 140A, high-k 140B, cap layer 1 140C (e.g., TiN, SiN, CHM or oxides such as SiOx), and the last material is cap layer 2 140D (e.g., TiN, SiOx, CHM or amorphous silicon (a-Si)). The transition material 140A may comprise SiOx, SiOxCN1-x, and the like. If the channel material comprises Ge or any group IV semiconductors or group III-V semiconductors, then the transition material 140A may comprise oxides that are suitable for those channel materials, such as GeOx and the like for Ge.

In this case, the fluorine 122 is implanted after the last material, cap layer 2 140D, is deposited on the cap layer 1 140C. As shown, fluorine 122 is located or distributed in all of the materials comprising the multilayer high-k gate dielectric stack 140 (centered in cap layer 2 140D) and does not cross interface 204B into the channel regions 113.

FIG. 2D shows an embodiment where the fluorine 122 is implanted within the multilayer high-k gate dielectric stack 140 after a second to last material of the multilayer high-k gate dielectric stack 140 is deposited. In this example, the plurality of materials 140A-140D comprising the multilayer high-k gate dielectric stack 140 comprises transition material 140A, high-k 140B, cap layer 1 140C, and cap layer 2 140D. In this case, the fluorine 122 is implanted after the second to last material, cap layer 1 140C, is deposited on the high-k 140B. After the fluorine 122 is implanted post cap layer 1, the cap layer 2 140D is deposited and annealed. This results in the fluorine 122 being located or distributed in all of the materials comprising the multilayer high-k gate dielectric stack 140 (centered in the cap layer 1 140C) and crosses interface 204C into the channel regions 113 in the substrate 101. If one or more other materials (not shown) are deposited prior to the fluorine 122 implant, then the fluorine 122 may also extend above the multilayer high-k gate dielectric stack 140 into the other materials.

The embodiments shown in FIG. 2C and FIG. 2D are similar but have different/higher performance reliability trade-offs. Process control knobs such as temperature of the implant and dose/energy can be tweaked to improve this trade-off. Performing the implant at an ion energy of approximately 550-650 eV, an ion range of 30-35 A, and at a higher implant temperature, e.g., >100 C, may help reduce implant damage and improve the trade-off.

According to the disclosed embodiments, performing an F-implant near the GOX transition layer interface provides several advantages. One advantage is that the F-implant does not result in transistor performance loss. Reliability improvements provided by the F-implant on PMOS include improved NBTI, breakdown voltage, hot carrier degradation, and 1/f noise. The F-implant also reduces the threshold voltage for P-MOS (VTP) to engineer lower VTP devices, and this capability is added without increasing the threshold voltage for N-MOS (VTN). Other improvements may include interface defect density at Si—OX interface improvement, transition layer quality improvement (porosity less, denser, and defect-free), change of K-value of the transition layer, and transition layer thickness change.

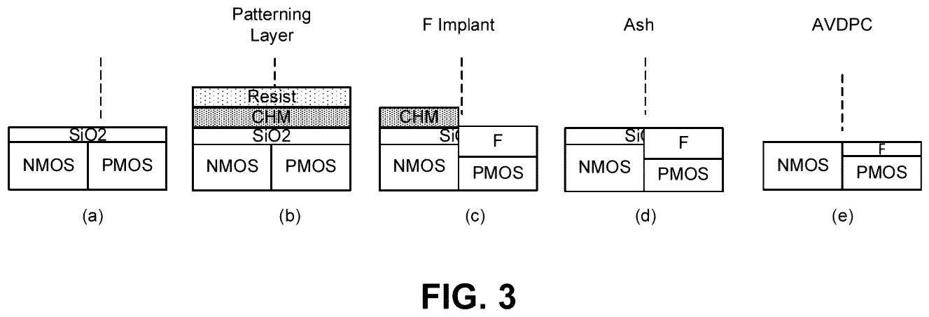

FIG. 3 shows an embodiment where patterning is used to selectively open a target layout configuration identified as requiring an NBTI benefit, which in this example is a PMOS layout. The F-implant is then performed in the target layout to minimize the impact on performance or even enhance it. Devices with different layout configurations can also be targeted through selective patterning and opening, not just NMOS and PMOS.

The process for implanting fluorine starts in step (a) with a silicon substrate with dummy silicon oxide material on top and over an NMOS layout and an adjacent PMOS layout, which is the target layout for the F-implant. Since a negative charge from the F-Implant may degrade NMOS Vt, and NMOS drive current degrades from columbic scattering, there is a need to block NMOS from the F-implant. NMOS layout and the PMOS layout are separated by depositing a patterning layer comprising a hard mask layer and a resist layer, and opening the patterning layer over the PMOS layout so that the patterning layer remains over the NMOS area but not the PMOS area, as shown in step (b). The F-implant is then performed only in the PMOS area due to the presence of the patterning layer over the NMOS area, shown in step (c). Any type of targeted area besides PMOS or NMOS may be selectively opened in this fashion. The patterning layer is then removed by Ash over the NMOS, shown in step (d). Finally, the dummy silicon oxide is also removed by a gate oxide clean (AVDPC) from the NMOS layout, shown in step (e). The process leaves F-implanted PMOS at the location of the GOX transition layer interface and the process continues with the fabrication of a permanent gate over the interface (not shown).

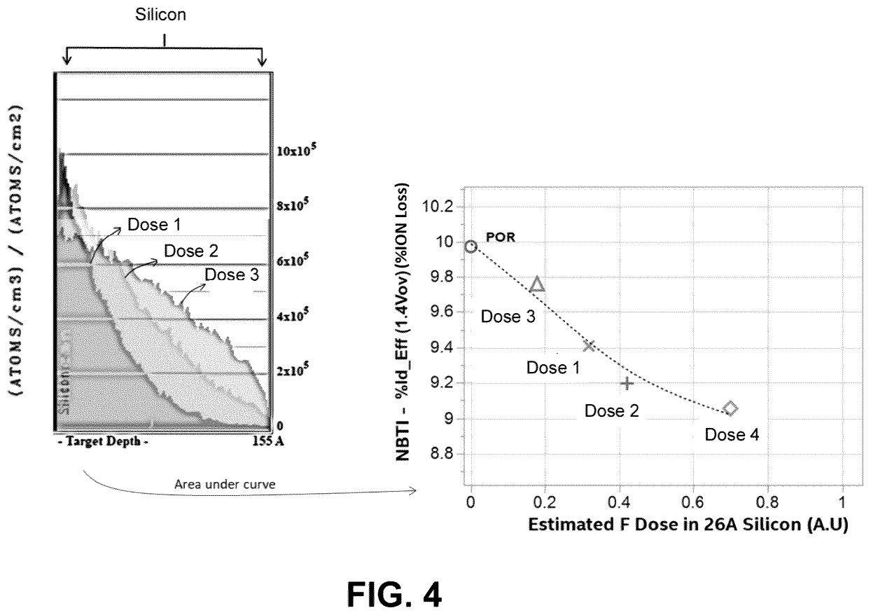

FIG. 4 illustrates graphs of simulation result profiles when fluorine is implanted in the dummy oxide to improve the amount of F-dose in silicon. The left graph shows fluorine dosages versus a target depth for the F-implant, and the right graph shows an associated area under the curve showing NBTI versus fluorine dosages in the silicon. The y-axis of the left graph shows different profiles of the density of fluorine atoms from 2×10⁵ to 10×10⁵ (atoms cm³/atoms cm²) in the substrate resulting from F-implant dosage/energies of dose 1, dose 2, dose 3, and dose 4. As an example, doses 1-4 may range from 1E14 to 7E-14. The x-axis shows dosage depths from 0 to 155A in the silicon starting at the interface. The profiles show a reduction in the density of fluorine atoms in the substrate as the target depth becomes greater. The lowest dosage, e.g., dose 1, may result in the fluorine being concentrated in the substrate near the interface and dropping in density as depth increases. The y-axis of the right graph shows percent ion loss, while the x-axis shows the area under the curve simulating different F doses in the silicon. For example, at dose 4, the simulation estimates that the fluorine dose in 26A silicon (½ fin width) is approximately 0.07, and the total NBTI benefit gained is directly proportionate to the number of fluorine atoms in the silicon.

Generally, a method for fabricating an IC device configured with transistor functionality may include forming an implant mask on a substrate and over a channel region between source and drain regions in the substrate. In one embodiment, the implant mask may comprise a dummy gate oxide (GOX). Fluorine is implanted in the implant mask layer over the channel region, resulting in the fluorine being located in both the implant mask and the substrate. The implant mask is subsequently removed. In one embodiment, this implant mask could comprise but not limited to Silicon (Si), Oxide (Ox), Nitride (N), or CHM. A multilayer high-k gate dielectric stack is formed on the substrate in the channel region over the fluorine. A gate electrode is then formed over and on the topmost material in the multilayer high-k gate dielectric stack.

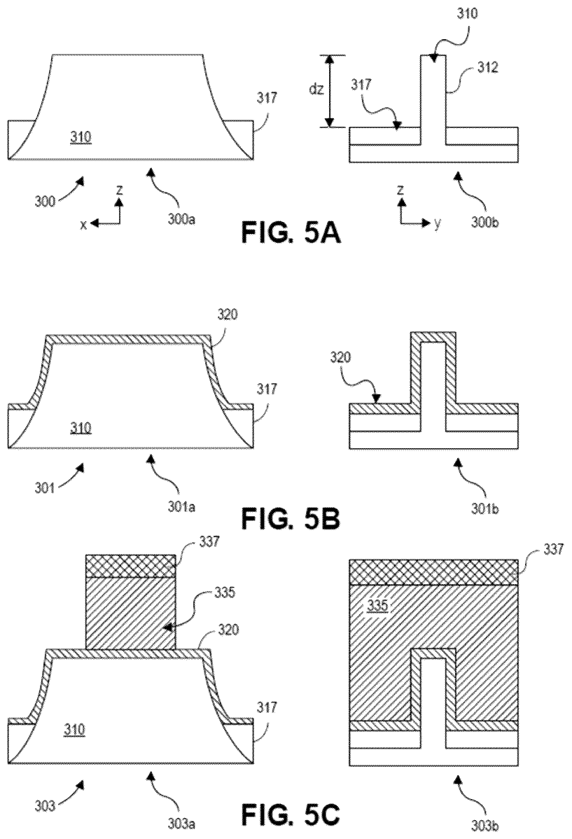

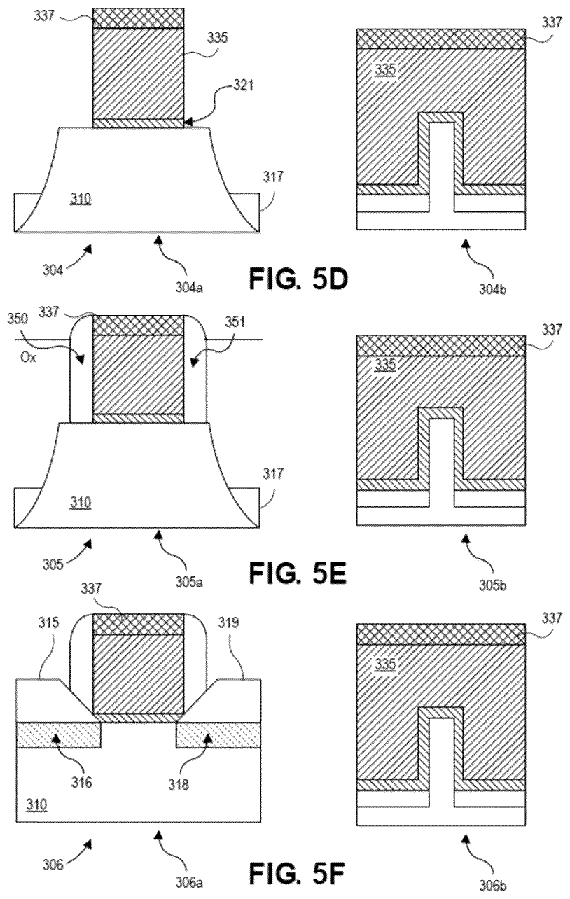

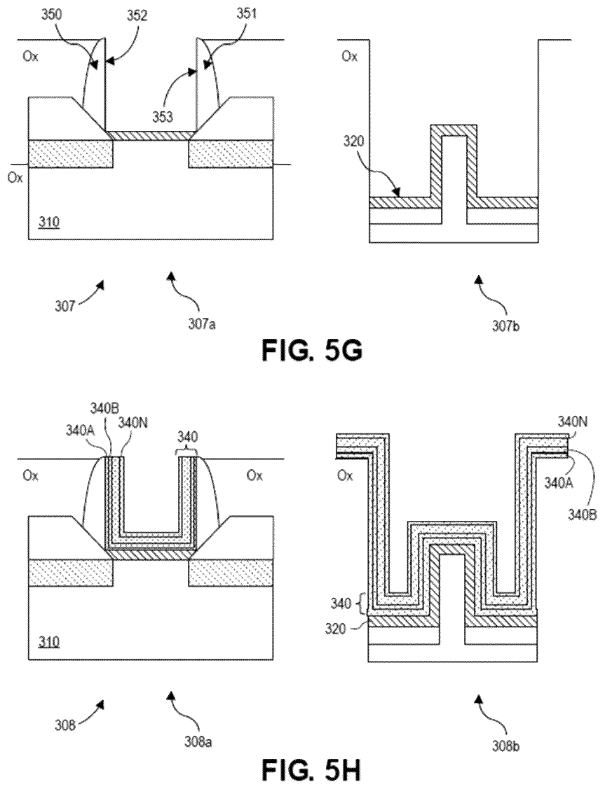

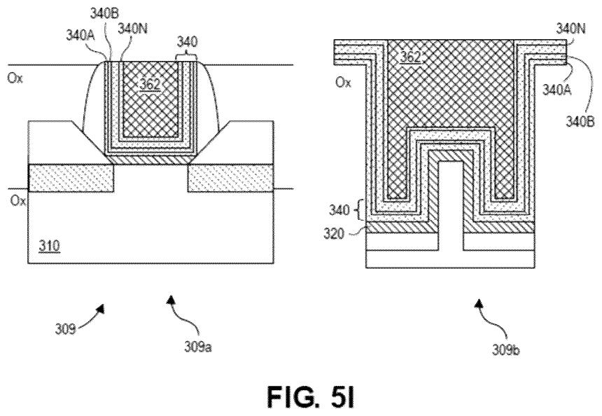

FIGS. 5A-5I illustrate cross-sectional views for respective stages 300-309 of processing to fabricate an IC device (configured to provide transistor functionality) having a multilayer high-k gate stack extending under a gate structure and over an existing semiconductor fin structure. For each of stages 300-309, FIGS. 5A-5I show respective median (y-z plane) cross-sectional views 300a-309a and respective transverse (x-z plane) cross-sectional views 300b-309b.

FIG. 5A shows the process after stage 300 in which a fin structure (such as the illustrative fin 310 shown) is formed extending through a trench which is formed at least in part by a trench dielectric 317. Fin 310 includes some or all of the features of fin structure 110, for example. In an embodiment, fin 310 comprises one or more semiconductor materials and forms side surfaces including, for example, the illustrative side 312 shown. Side 312 has a vertical (z-axis) span “dz” which extends at least between the top of fin 310 and a horizontal surface, such as that of trench dielectric 317. In an example embodiment, such a vertical span is in a range of 10 nm to 200 nm. However, such dimensions may vary according to implementation-specific details, in different embodiments. The formation of fin 310 and trench dielectric 317 includes operations that are adapted, for example, from conventional techniques for fabricating finFET transistors.

FIG. 5B shows the process after stage 301 in which a dielectric layer 320 is formed to extend, e.g., along the x-axis dimension shown-across and over at least a portion of fin 310. At least a portion of dielectric layer 320 is to serve as a structure to promote electrical insulation in a transistor structure. At least a portion of dielectric layer 320—e.g., a portion which is adjacent to, and conformal with, some of fin 310—is to provide at least part of a gate dielectric structure. By way of illustration and not limitation, a material of the dielectric layer 320 comprises silicon and one of oxygen, nitrogen, or carbon—e.g., wherein the dielectric layer 320 material is one of silicon oxides (SiO₂), silicon oxynitrides (SiON), silicon nitrides (SiN), silicon carbonitrides (SiCN), carbon-doped oxide (SiOC), or combinations thereof. However, in other embodiments, dielectric layer 320 includes any of a variety of suitable materials that are adapted from conventional techniques for providing electrical insulation for non-planar transistors. In some embodiments, an average thickness of the dielectric layer 320 is equal to or less than 40 Angstroms (Å) thick—e.g., in a range of 5 Å to 40 Å and, in some embodiments, in a range of 5 Å to 20 Å. However, such dimensions may vary according to implementation-specific details, in different embodiments. In an embodiment, the formation of the dielectric layer 320 includes any of a variety of additive processes (such as chemical vapor deposition, atomic layer deposition, or the like) adapted, for example, from conventional semiconductor fabrication techniques.

FIG. 5C shows the process after stage 303 in which to form spacers that may correspond to spacers 150, 151 (FIG. 1B), a dummy (i.e., sacrificial) gate 335 is first formed over a portion of fin 310. A portion of fin 310 under dummy gate 335 provides a channel region 113 (FIG. 1B) of a transistor structure (or other such IC device). Dummy gate 335 includes a layer of material such as polysilicon (e.g., doped, undoped, amorphous, crystalline, or the like), or any of various suitable carbon or nitride-based materials, for example. In an example embodiment, the formation of dummy gate 335 includes forming a patterned resist or hard mask 337 on dielectric layer 320 and depositing a dummy gate material through the patterned resist mask. Any of a variety of known mask, patterning, deposition and/or etch methods and techniques can be used to form dummy gate 335, in various embodiments. At this point, the F-implant can be optionally performed as described above.

FIG. 5D shows the process after stage 304 in which etching and/or other subtractive processing is performed, e.g., with a patterned mask 337 to remove respective portions of dielectric layer 320 that are not under dummy gate 335. Such subtractive processing leaves portion 321 of dielectric layer 320 in this embodiment.

FIG. 5E shows the process after stage 305 in which spacers 350 and 351 are formed each at a respective opposite sidewall of dummy gate 335. Spacers 350 and 351 include features of insulation spacers 150 and 151 (FIG. 1 B) except where (for example) portions 321 abuts against and does not extend under, spacer portions 350 and 351.

FIG. 5F shows the process after stage 306 in which doped source and drain regions 316 and 318 are formed in portions of fin 310 that are on opposite respective sides of channel region 113 (FIG. 1B). Other transistor structures formed by the additional fabrication include raised epitaxial (epi) source or drain regions 315 and 319 each extending over a respective one of the doped source or drain regions 316, 318—source or drain contact structures (not shown), and/or the like. Such additional fabrication includes processes that, for example, are adapted from conventional mask, patterning, etching, deposition, doping, polishing, and/or other techniques.

FIG. 5G shows the process after stage 307 in which dummy gate 335 is etched or otherwise removed. Removal of dummy gate 335 exposes respective side surfaces 352 and 353 of spacers 350 and 351. In some embodiments, etching to remove dummy gate 335 also removes a dummy oxide (if any) that was previously deposited on layer 320. Note, that layer 320 is subsequently removed and then reformed. In embodiments, the dummy oxide and reformed dummy oxide may comprise SiO₂ or SiON for example. If the F-implant has not yet been performed, then the F-implant can be optionally performed here, as described above.

FIG. 5H shows the process after stage 308 in which a multilayer high-k gate dielectric stack 340 comprising at least a first high-k material 340A and optional additional high-k materials up to an n^{th} high-k material 340N are sequentially formed. The first high-k material 340A extends across and over fin 310 in a region between spacers 350 and 351 such that the first high-k material 340A is adjacent and conformal to spacer sides 352 and 353 and dielectric layer 320. After the first high-k material 340A is formed, each successive high-k material is conformal to the previous high-k material. If the F-implant has not yet been performed, then the F-implant can be optionally performed after deposition of any of the material layers comprising the multilayer high-k gate dielectric stack 340, as described above.

Formation of the multilayer high-k gate dielectric stack 340 comprises deposition of dielectric materials that have a higher dielectric constant than that of dielectric layer 320. In embodiments, the high-k materials used to form multilayer high-k gate dielectric stack 340 comprise oxygen and a metal which, for example, includes, but is not limited to, one or more of aluminum (Al), tantalum (Ta), hafnium (Hf), zirconium (Zr), lanthanum (La), titanium (Ti) magnesium (Mg) or manganese (Mn). For example, in some embodiments, the second dielectric material includes hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof.

In various embodiments, the multilayer high-k gate dielectric stack 340 may be approximately 1 to 100 Å in thickness. The various high-k material layers may be the same or different thicknesses, with a minimum thickness of 5 Å each. For example, one high-k material layer may be 5 Å, while the next is 1 nanometer, and the like.

In some embodiments, fabrication of one or more of layers 320, multilayer high-k gate dielectric stack 340, and/or spacers 350 and 351 comprise one or more operations which, for example, are adapted from conventional semiconductor fabrication techniques such as mask, lithography, deposition (e.g., chemical vapor deposition), etching and/or other processes. Some of these conventional techniques are not detailed herein to avoid obscuring certain features of various embodiments.

FIG. 5I shows the process after stage 309 in which a gate electrode structure 362 is formed on the multilayer high-k gate dielectric stack 340, e.g., using operations adapted from conventional metallization and/or other deposition techniques.

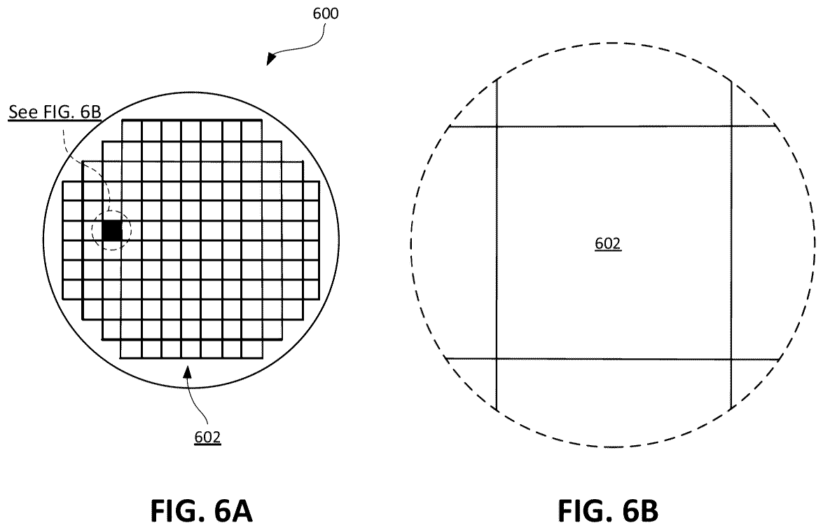

Referring to FIGS. 6A and 6B, a wafer 600 may be composed of semiconductor material and may include one or more dies 602 having integrated circuit (IC) structures formed on the surface of the wafer 600. Each of the dies 602 may be a repeating unit of a semiconductor product that includes any suitable IC (e.g., ICs including NBTI reduction based on a fluorine implant, such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having NBTI reduction based on a fluorine implant as disclosed herein may take the form of the wafer 600 (e.g., not singulated) or the form of the die 602 (e.g., singulated). The die 602 may include one or more embedded non-volatile memory structures and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on the same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

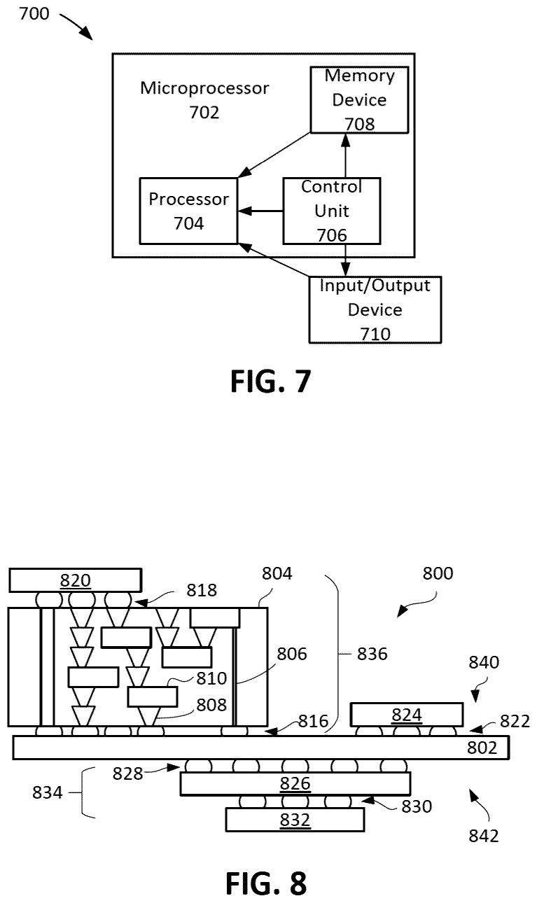

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations that are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes NBTI reduction based on a fluorine implant, such as those described herein.

FIG. 8 is a cross-sectional side view of an integrated circuit (IC) device assembly that may include NBTI reduction based on a fluorine implant, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of a multilayer high-k gate dielectric, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to the same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

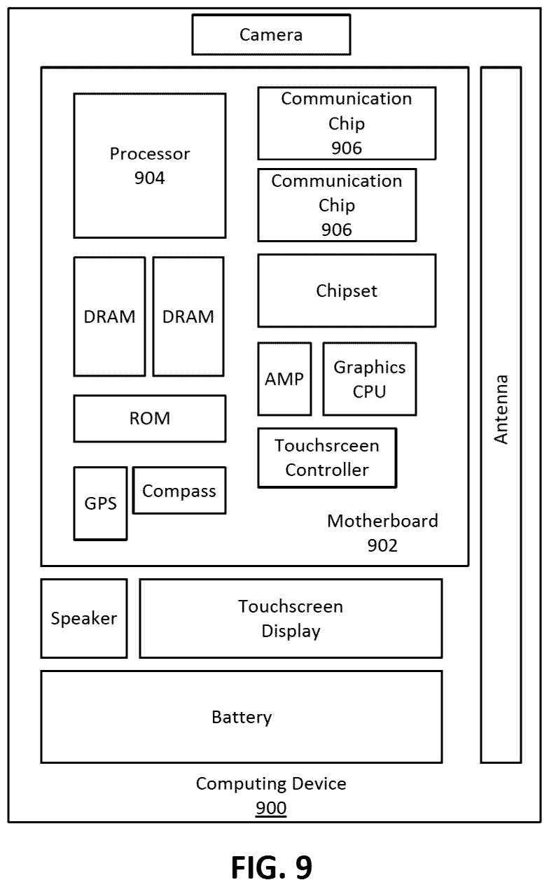

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter-range wireless communications such as Wi-Fi and Bluetooth and a second communication chip 906 may be dedicated to longer-range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes NBTI reduction based on a fluorine implant, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip 906 includes NBTI reduction based on a fluorine implant, in accordance with implementations of embodiments of the disclosure.

In further implementations, another component housed within the computing device 900 may contain an integrated circuit die that includes NBTI reduction based on a fluorine implant, in accordance with implementations of embodiments of the disclosure.

In various implementations, the computing device 900 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include a substrate and multilayer high-k gate dielectric having a fluorine implant adjacent to a gate oxide interface.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above-detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: An integrated circuit structure comprises a fin extending from a substrate, the fin comprising source and drain regions, and a channel region between the source and drain regions. A multilayer high-k gate stack comprising a plurality of materials extends conformally over the fin over the channel region. A gate electrode is over and on a topmost in the multilayer high-k gate stack. Fluorine is implanted in the substrate beneath the multilayer high-k gate stack or in the plurality of materials comprising the multilayer high-k gate stack.

Example embodiment 2: The integrated circuit structure of embodiment 1, wherein the multilayer high-k gate stack comprises any combination of: at least one of Silicon (Si), Oxide (Ox), Nitride (N), Titanium (Ti), Tantalum (Ta), and Amorphous silicon (a-Si); and at least one of Hafnium (Hf), Zirconium (Zr), Aluminum (Al), and Cyanide (CN).

Example embodiment 3: The integrated circuit structure of embodiment 1 or 2, wherein the fluorine is located only in the substrate adjacent to the multilayer high-k gate stack.

Example embodiment 4: The integrated circuit structure of embodiment 1 or 2, wherein the fluorine is implanted only in the multilayer high-k gate stack.

Example embodiment 5: The integrated circuit structure of embodiment 1 or 2, wherein the fluorine is implanted in both the substrate and the multilayer high-k gate stack.

Example embodiment 6: The integrated circuit structure of embodiment, 1, 2, or 4, wherein the fluorine is located in all of the plurality of materials comprising the multilayer high-k gate stack and does not cross into the channel region in the substrate.

Example embodiment 7: An integrated circuit structure comprises source and drain regions in a substrate, and a channel region between the source and drain regions. A multilayer high-k gate stack comprising a plurality of materials extends conformally over the channel region. A gate electrode is over and on a topmost in the multilayer high-k gate stack. Fluorine is implanted in the substrate beneath the multilayer high-k gate stack or in the plurality of materials comprising the multilayer high-k gate stack.

Example embodiment 8: The integrated circuit structure of embodiment 7, wherein the multilayer high-k gate stack comprises any combination of: at least one of Silicon (Si), Oxide (Ox), Nitride (N), Titanium (Ti), Tantalum (Ta), and Amorphous silicon (a-Si); and at least one of Hafnium (Hf), Zirconium (Zr), Aluminum (Al), and Cyanide (CN).

Example embodiment 9: The integrated circuit structure of embodiment 7 or 8, wherein the fluorine is located only in the substrate adjacent to the multilayer high-k gate stack.

Example embodiment 10: The integrated circuit structure of embodiment 7 or 8, wherein the fluorine is implanted only in the multilayer high-k gate stack.

Example embodiment 11: The integrated circuit structure of embodiment 7 or 8, wherein the fluorine is implanted in both the substrate and the multilayer high-k gate stack.

Example embodiment 12: The integrated circuit structure of embodiment 7, 8, or 10 wherein the fluorine is located in all of the plurality of materials comprising the multilayer high-k gate stack and does not cross into the channel region in the substrate.

Example embodiment 13: A method for fabricating an integrated circuit device includes forming an implant mask on a substrate and over a channel region between source and drain regions in the substrate. Fluorine is implanted in the implant mask over the channel region, resulting in the fluorine being located in both the implant mask and the substrate, and the implant mask is then removed. A multilayer high-k gate dielectric stack is formed on the substrate in the channel region over the fluorine. A gate electrode is then formed over and on the topmost high-k material in the multilayer high-k gate dielectric stack.

Example embodiment 14: The method of embodiment 13, further comprising: forming the multilayer high-k gate stack with any combination of at least two of: Silicon (Si), Oxide (Ox), Nitride (N), Titanium (Ti), Tantalum (Ta), Amorphous silicon (a-Si), Hafnium (Hf), Zirconium (Zr), Aluminum (Al), and Cyanide (CN).

Example embodiment 15: The method of embodiment 13 or 14, further comprising: implanting the fluorine at a dose of approximately 1e14 to 7e14 and at a temperature of approximately 25 C to 150 C.

Example embodiment 16: The method of embodiment 13, 14, or 15, wherein a fin extends from the substrate and includes the source and drain regions, the method further comprising: implanting the fluorine in at least two sides of a fin structure.

Example embodiment 17: The method of embodiment 13, 14, 15, or 16, further comprising: performing a first fluorine implant on one side of the fin and performing a second fluorine implant on an opposite side of the fin.

Example embodiment 18: The method of embodiment 13, 14, 15, 16, or 17, further comprising: performing the first fluorine implant and the second fluorine implant at a tilt angle of approximately 20°-45° from vertical.

Example embodiment 19: The method of embodiment 13, 14, 15, 16, 17, or 18 further comprising forming the implant mask over a first layout and a target layout, the target layout being identified as requiring a negative bias temperature instability benefit. A patterning layer is deposited over the implant mask, and selectively opening the patterning layer over the target layout so that the patterning layer remains over the first layout. Fluorine is implanted in the implant mask such that fluorine is implanted in the target layout at a location of a GOX transition layer interface, but the fluorine is blocked from the first layout due to the patterning layout. The patterning layer is removed from the first layout.

Example embodiment 20: The method of embodiment 19, wherein the first layout comprises NMOS and the target layout comprises PMOS.

What is claimed is:

1. An integrated circuit structure, comprising:
a fin extending from a substrate, the fin comprising source and drain regions, and a channel region between the source and drain regions;
a multilayer high-k gate stack comprising a plurality of materials extending conformally over the fin over the channel region;
a gate electrode over and on a topmost material in the multilayer high-k gate stack; and
fluorine implanted in the substrate beneath the multilayer high-k gate stack or in the plurality of materials comprising the multilayer high-k gate stack.

2. The integrated circuit structure of claim 1, wherein the multilayer high-k gate stack comprises any combination of:
at least one of Silicon (Si), Oxide (Ox), Nitride (N), Titanium (Ti), Tantalum (Ta), and Amorphous silicon (a-Si); and
at least one of Hafnium (Hf), Zirconium (Zr), Aluminum (Al), and Cyanide (CN).

3. The integrated circuit structure of claim 1, wherein the fluorine is located only in the substrate adjacent to the multilayer high-k gate stack.

4. The integrated circuit structure of claim 1, wherein the fluorine is implanted only in the multilayer high-k gate stack.

5. The integrated circuit structure of claim 1, wherein the fluorine is implanted in both the substrate and the multilayer high-k gate stack.

6. The integrated circuit structure of claim 1, wherein the fluorine is located in all of the plurality of materials comprising the multilayer high-k gate stack and does not cross into the channel region in the substrate.

7. An integrated circuit structure, comprising:
source and drain regions in a substrate;
a channel region between the source and drain regions;
a multilayer high-k gate stack comprising a plurality of materials extending conformally over the channel region;
a gate electrode over and on a topmost material in the multilayer high-k gate stack; and
fluorine implanted in the channel region beneath the multilayer high-k gate stack or in the plurality of materials comprising the multilayer high-k gate stack.

8. The integrated circuit structure of claim 7, wherein the multilayer high-k gate stack comprises any combination of:
at least one of Silicon (Si), Oxide (Ox), Nitride (N), Titanium (Ti), Tantalum (Ta), and Amorphous silicon (a-Si); and
at least one of Hafnium (Hf), Zirconium (Zr), Aluminum (Al), and Cyanide (CN).

9. The integrated circuit structure of claim 7, wherein the fluorine is located only in the substrate adjacent to the multilayer high-k gate stack.

10. The integrated circuit structure of claim 7, wherein the fluorine is implanted only in the multilayer high-k gate stack.

11. The integrated circuit structure of claim 7, wherein the fluorine is implanted in both the substrate and the multilayer high-k gate stack.

12. The integrated circuit structure of claim 7, wherein the fluorine is located in all of the plurality of materials comprising the multilayer high-k gate stack and does not cross into the channel region in the substrate.

13. A method of fabricating an integrated circuit device, the method comprising:
forming an implant mask on a substrate and over a channel region between source and drain regions in the substrate;
implanting fluorine in the implant mask over the channel region, resulting in the fluorine being located in both the implant mask and the substrate;
removing the implant mask;
forming a multilayer high-k gate stack on the substrate in the channel region over the fluorine; and
forming a gate electrode over and on a topmost material in the multilayer high-k gate stack.

14. The method of claim 13, further comprising: forming the multilayer high-k gate stack with any combination of at least two of: Silicon (Si), Oxide (Ox), Nitride (N), Titanium (Ti), Tantalum (Ta), Amorphous silicon (a-Si), Hafnium (Hf), Zirconium (Zr), Aluminum (Al), and Cyanide (CN).

15. The method of claim 13, further comprising: implanting the fluorine at a dose of approximately 1e14 to 7e14 and at a temperature of approximately 25 C to 150 C.

16. The method of claim 13, wherein a fin extends from the substrate and includes the source and drain regions, the method further comprising: implanting the fluorine in at least two sides of a fin structure.

17. The method of claim 16, further comprising: performing a first fluorine implant on one side of the fin and performing a second fluorine implant on an opposite side of the fin.

18. The method of claim 17, further comprising: performing the first fluorine implant and the second fluorine implant at a tilt angle of approximately 20°-45° from vertical.

19. The method of claim 13, further comprising:
forming the implant mask over a first layout and a target layout, the target layout being identified as requiring a negative bias temperature instability benefit;
depositing a patterning layer over the implant mask, and selectively opening the patterning layer over the target layout so that the patterning layer remains over the first layout;
implanting fluorine in the implant mask such that fluorine is implanted in the target layout at a location of a GOX transition layer interface, but the fluorine is blocked from the first layout due to the patterning layout; and
removing the patterning layer from the first layout.

20. The method of claim 19, wherein the first layout comprises NMOS and the target layout comprises PMOS.
